(19) United States
(12) Patent Application Publication
(10) Pub. No.: US 2006/0281301 A1
(43) Pub. Date: Dec. 14, 2006

(54) Method for manufacturing dual damascene pattern

(76) Inventor: Shin Eun Jong, Seoul (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/449,275

(22) Filed: Jun. 8, 2006

(30) Foreign Application Priority Data
Jun. 8, 2005 (KR) 10-2005-0048879

(51) Int. Cl. H01L 21/4763

(52) U.S. Cl. 438/624; 438/638; 438/798

(57) ABSTRACT

Normal+Times New Roman, Justified, Line spacing: 1.5 lines A method for forming a dual damascene pattern is provided. According to the method, a diffusion barrier layer and an interlayer insulation layer are formed on a substrate. A surface of the interlayer insulation layer is processed to reduce adhesion and deformation. A capping layer is then formed on the interlayer insulation layer. Subsequently, the capping layer and the interlayer insulation layer are patterned to form a via hole, and the via hole is filled with a light absorption layer. After a photoresist pattern for a trench is formed on the light absorption layer, exposed portions of the light absorption layer, the interlayer insulation layer, and the capping layer are etched to a predetermined depth to form a trench. Then the photoresist pattern for the trench and the light absorption layer remaining in the via hole are removed.

### RELATED APPLICATION

This application claims the benefit under 35 U.S.C. §119(e) of Korean Patent Application No. 10-2005-0048879, filed Jun. 8, 2005, which is incorporated herein by reference in its entirety.

### FIELD OF THE INVENTION

The present invention relates to a dual damascene process using a material having a low dielectric constant, and more particularly, to a method for manufacturing a dual damascene pattern that increases reliability of a device by performing a plasma pre-process using an inert gas on a surface of a material having a low dielectric constant to form an interlayer insulation layer.

### BACKGROUND OF THE INVENTION

As the semiconductor industry develops with a focus on very large scale integrated (VLSI) circuits, the geographic shape of a device is reducing in size to a sub-half-micron region, and the circuit density is increasing in aspects of high performance and reliability. Reflecting such trends, copper thin film, which has a high melting point compared to aluminum, has high resistance against electro-migration (EM) when used to form a metal wiring of a semiconductor device. Accordingly, the copper thin film may enhance reliability of the semiconductor device, and because of its low specific resistance, it may increase signal delivery speed. Therefore, the copper thin film is used as an interconnection material useful for integrated circuits (ICs). Also, as a semiconductor device becomes highly integrated and technology develops, parasitic capacitance between wirings becomes problematic. When the parasitic capacitance increases, a resistance capacitance (RC) delay increases, power consumption increases, and noises caused by mutual crosstalk occur, which hinders a high speed device. Therefore, an insulation material having a low dielectric constant (low-k) of 3 or lower such as a porous oxide is used for an interlayer insulation layer.

Wiring processes are performed using an insulation material having a low dielectric constant, but the etching characteristic of copper is very poor. Therefore, the dual damascene process is widely used in order to solve this problem.

The dual damascene process is performed in various ways, for example, buried via, via first, trench first, and self aligned type methods.

An increase in the speed of a complementary metal oxide semiconductor (CMOS) logic device primarily depends on reducing gate delay time using the reduction of a gate's length. As semiconductor devices become highly integrated, an RC delay caused by back end of line (BEOL) metallization determines the speed of a semiconductor device. In order to reduce the RC delay, as mentioned above, a metal having low resistance such as copper is used for a metal wiring material, and an interlayer insulation layer is formed of a material having a low dielectric constant, and a dual damascene process is used.

FIGS. 1A to 1F are sectional views explaining a method for manufacturing a dual damascene pattern according to a prior related art.

Referring to FIG. 1A, a substrate 10 in which a lower wiring 11 has been formed is provided, and a diffusion barrier layer 12 is formed on the entire structure including the lower wiring 11. When the lower wiring 11 is formed of copper, the diffusion barrier layer 12 prevents the copper from being oxidized and prevents copper ions from diffusing to the outside. Also, the diffusion barrier layer 12 protects the lower wiring 11 while a via hole is formed during a subsequent process.

Referring to FIG. 1B, an interlayer insulation layer 13 and a capping layer 14 are formed on the diffusion barrier layer 12. A photoresist pattern 15, having openings where a via hole is to be formed, is formed on the capping layer 14.

The interlayer insulation layer 13 is formed of a material having a low dielectric constant in order to solve a problem caused by parasitic capacitance between wirings. The capping layer 14 is formed in order to absorb moisture from the interlayer insulation layer 13 formed of the low dielectric constant material or to prevent damage caused during a subsequent process. The capping layer 14 is generally formed of a nitride such as PE-TEOS, SiN, SiON, Si₃N₄.

Referring to FIG. 1C, the capping layer 14 and the interlayer insulation layer 13 are etched through a via-etching process that uses the photoresist pattern 15 as an etch mask to form a via hole 16. At this point, the diffusion barrier layer 12 serves as an etch stop layer. After that, the photoresist pattern 15 is removed.

Referring to FIG. 1D, a light absorption layer 100 is coated on the entire structure including in the via hole 16 in order to bury the via hole 16. A photoresist pattern 17, having openings where a trench is to be formed, is formed on the light absorption layer 100. An organic bottom (B)-antireflection layer (ARC) is generally used for the light absorption layer 100.

Referring to FIG. 1E, exposed portions of the light absorption layer 100, the interlayer insulation layer 13, and the capping layer 14 are etched to a predetermined depth using the photoresist pattern 17 as an etch mask to form a trench 18. After that, the photoresist pattern 17 for the trench and the light absorption layer 100 are removed, so that a dual damascene pattern consisting of the via hole 16 and the trench 18 is formed.

Referring to FIG. 1F, an upper wiring 19 that is connected to the lower wiring 11 is formed within the dual damascene pattern.

The above-described method for forming the dual damascene pattern according to the related art is a via first type method. A trench first type method where a trench is formed first and a via hole is formed later, a buried via type method, and a self aligned method are also used in the prior art. In a dual damascene pattern, a SiOC film, which is a material having a low dielectric constant (low-k), is widely used for the interlayer insulation layer 13. However, the material having the low dielectric constant has a reliability problem during integration such as electro-migration (EM), stress-migration (SM), and a temperature dependent dielectric breakdown (TDDB) due to its characteristic. Particularly, when SiOC widely used for a material having a low dielectric constant is used, IMD adhesion and delamination emerge as problems.

FIG. 2A illustrates trench side wall delamination and poor adhesion. When an ashing process is performed on a material having a low dielectric constant such as SiOC, carbon loss occurs. Therefore, delamination caused by boundary damage between SiOC and a SiO₂ film of an IMD sidewall may be generated as illustrated in FIG. 2A. Also, an adhesion problem between SiOC of the interlayer insulation layer 23 and the SiO2 film of the capping layer 24 may be generated due to a carbon group.

FIG. 2B illustrates a metal bridge 26 formed due to the delamination and adhesion problems. When a portion between the capping layer 24 and the interlayer insulation layer 23 is delaminated or adhesion between them is not completed, a metal bridge is generated. A metal bridge occurs where copper is introduced to a gap between the capping layer 24 and the interlayer insulation layer 23 and is injected to a hole, which reduces a device's quality.

FIG. 2C illustrates an ideal dual damascene process where delamination and adhesion problems are not generated.

### SUMMARY OF THE INVENTION

Accordingly, the present invention is directed to a method for manufacturing a dual damascene pattern that addresses and/or substantially obviates one or more problems, limitations, and/or disadvantages of the related art.

An object of the present invention is to provide a method for manufacturing a dual damascene pattern capable of reducing adhesion and delamination by forming an interlayer insulation layer and then performing a plasma pre-process using an inert gas.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a method for forming a dual damascene pattern, the method incorporating: forming a diffusion barrier layer and an interlayer insulation layer on a substrate; processing a surface of the interlayer insulation layer; forming a capping layer on the interlayer insulation layer; patterning the capping layer and the interlayer insulation layer to form a via hole; filling the via hole with a light absorption layer; forming a photoresist pattern for a trench on the light absorption layer; etching exposed portions of the light absorption layer, the interlayer insulation layer, and the capping layer to a predetermined depth to form a trench; removing the photoresist pattern for the trench; and removing the light absorption layer remaining in the via hole.

In another aspect of the present invention, there is provided a method for forming a dual damascene pattern, the method incorporating: forming a first insulation layer on a substrate; processing a surface of the first insulation layer; and forming a second insulation layer on the first insulation layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1A to 1F are cross-sectional views explaining a method for manufacturing a dual damascene pattern according to a prior related art;

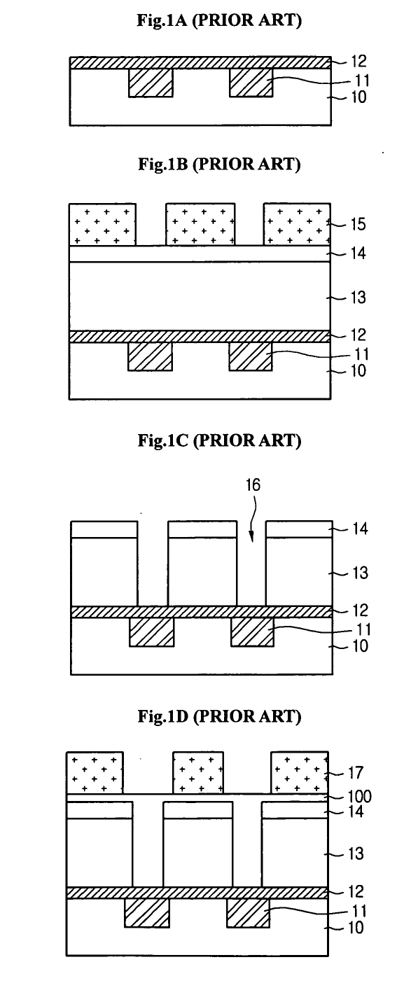

FIG. 2A is a view illustrating delamination;

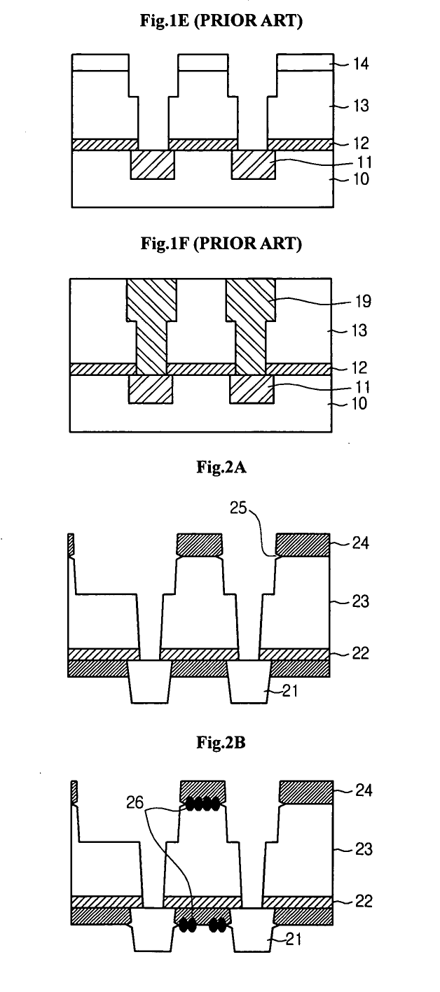

FIG. 2B is a view illustrating a metal bridge;

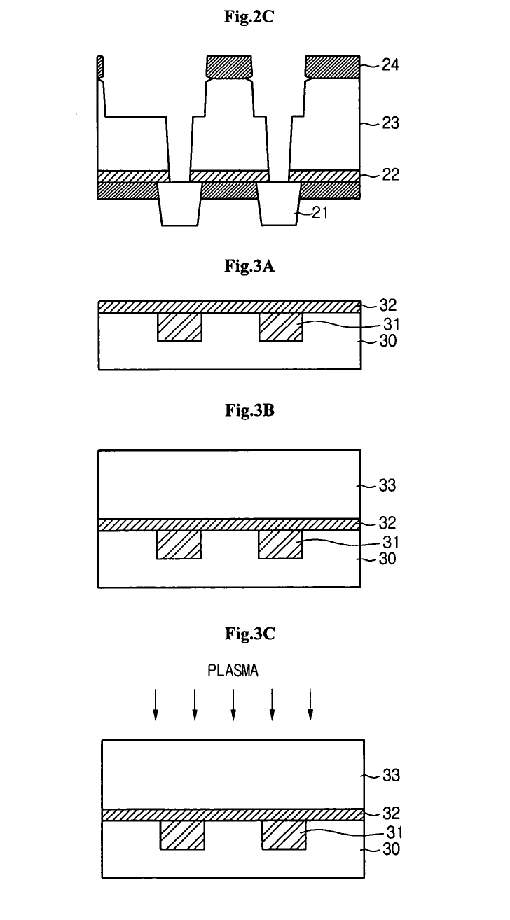

FIG. 2C is a cross-sectional view of a normal dual damascene pattern; and

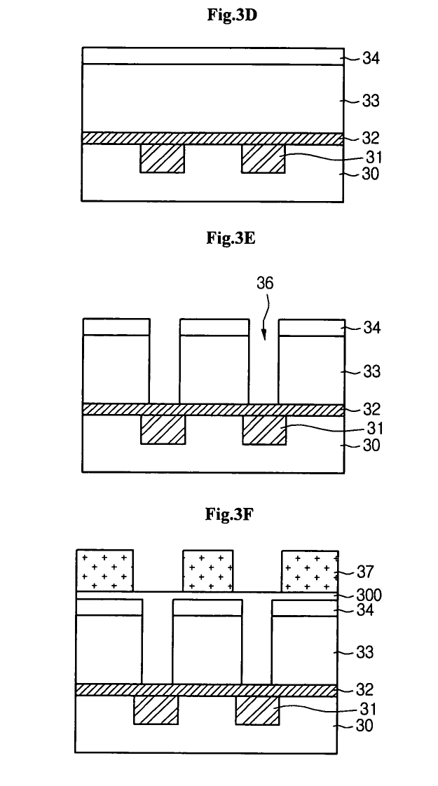

FIGS. 3A to 3H are cross-sectional views explaining a method for manufacturing a dual damascene pattern according to an embodiment of the present invention.

### DETAILED DESCRIPTION OF THE INVENTION

Reference will now be made in detail to the preferred embodiments of the present invention, examples of which are illustrated in the accompanying drawings.

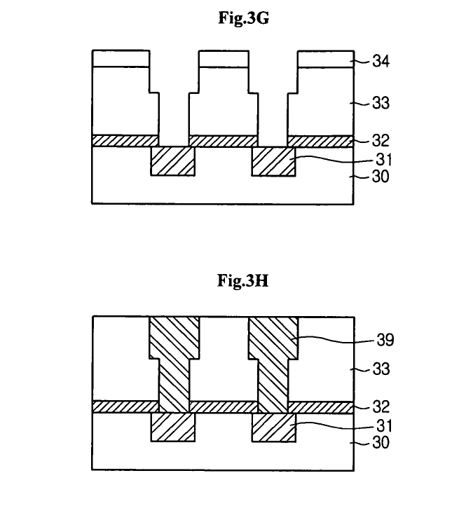

FIGS. 3A to 3H are cross-sectional views explaining a method for manufacturing a dual damascene pattern according to an embodiment of the present invention.

Referring to FIG. 3A, a substrate 30 incorporating a lower wiring 31 can be provided. A diffusion barrier layer 32 can be formed on the substrate 30 including the lower wiring 31. In embodiments where the lower wiring 31 is formed of copper, the diffusion barrier layer 32 can prevent the copper from being oxidized and can prevent copper ions from diffusing to the outside. In further embodiments the diffusion barrier layer 32 can protect the lower wiring 31 while a via hole is formed during a subsequent process.

Referring to FIGS. 3B and 3C, an interlayer insulation layer 33 having a low dielectric constant (low-k) can be formed on the diffusion barrier layer 32. The low dielectric constant material means can have enhanced insulation ability compared to a silicon oxide having a dielectric constant of 4 or lower.

SiOC is most widely used for the low dielectric constant material. In embodiments incorporating SiOC, the surface carbon density of increases after SiOC is coated on a substrate. Such an increase in the carbon density generates poor adhesion between the SiOC film and a capping layer formed on the SiOC film, and can cause delamination.

Referring to FIG. 3C, a plasma pre-process using an inert gas can be performed on the interlayer insulation layer 33 in order to prevent a metal bridge from being formed due to the above described poor adhesion and delamination. This pre-process can remove carbon groups on the surface of the interlayer insulation layer 33, and consequently, can reduce poor adhesion or delamination generated by the carbon group and can prevent reduction of device quality caused by a metal bridge. In a specific embodiment, an inert gas used for the plasma process may be one of Ar and He.

In one embodiment, the surface processing of the interlayer insulation layer 33 can be performed using a sputtering process that uses one of O₂ and H₂.

FIG. 3D illustrates a capping layer 34 coated on the interlayer insulation layer 33. The capping layer 34 can be formed in order to absorb moisture from the interlayer insulation layer 33 or to prevent damage caused during a subsequent process. The capping layer 34 is mainly formed of a nitride such as PE-TEOS, SiN, SiON, Si₃N₄.

Referring to FIG. 3E, a photoresist layer can be formed on the capping layer 34 and patterned into an etch pattern for forming via holes. Etching can then be performed to form a via hole 36.

Referring to FIG. 3F, a light absorption layer 300 can be formed on the entire structure including in the via hole 36 to bury the via hole 36. Then, a photoresist pattern 37, having openings where a portion in which a trench is to be formed, can be formed on the light absorption layer 300.

Referring to FIG. 3G, portions of the light absorption layer 300, the interlayer insulation layer 33, and the capping layer 34 are etched to a predetermined depth using the photoresist pattern 37 as an etch mask to form a trench 38. Then, the photoresist pattern 37, the light absorption layer 300, and the diffusion barrier layer 32 can be removed to expose the lower wiring 31.

Referring to FIG. 3H, an upper wiring 39 connected to the lower wiring 31 can be formed within the dual damascene pattern consisting of the via hole 36 and the trench 38. The upper wiring 39 can be formed of a conductive material such as Cu, W, and Al.

According to a method for forming a dual damascene pattern of the present invention, a carbon group on a surface of an interlayer insulation layer can be removed by performing a plasma process that uses an inert gas on the interlayer insulation layer, so that poor adhesion problems associated with a capping layer and delamination problem are reduced. Therefore, a metal bridge can be prevented, and reliability and product yields can be enhanced.

It will be apparent to those skilled in the art that various modifications and variations can be made in the present invention. Thus, it is intended that the present invention covers the modifications and variations of this invention provided they come within the scope of the appended claims and their equivalents.

I claim:

1. A method for forming a dual damascene pattern, comprising:
forming a diffusion barrier layer on a substrate;
forming an interlayer insulation layer on the diffusion barrier layer;
performing a plasma process to a surface of the interlayer insulation layer;
forming a capping layer on the interlayer insulation layer;
patterning the capping layer and the interlayer insulation layer to form a via hole;
filling the via hole with a light absorption layer;
forming a photoresist pattern for a trench on the light absorption layer;
etching exposed portions of the light absorption layer, the interlayer insulation layer, and the capping layer to form a trench;
removing the photoresist pattern for the trench; and
removing the light absorption layer remaining in the via hole.

2. The method according to claim 1, wherein the interlayer insulation layer is formed of a material having a low dielectric constant.

3. The method according to claim 2, wherein the material having the low dielectric constant contains carbon.

4. The method according to claim 3, wherein the performing a plasma process removes carbon from the material having the low dielectric constant.

5. The method according to claim 2, wherein the material having the low dielectric constant is SiOC.

6. The method according to claim 1, wherein the plasma process uses an inert gas.

7. The method according to claim 6, wherein the inert gas is He or Ar.

8. The method according to claim 1, wherein the plasma process uses O₂ or H₂.

9. The method according to claim 1, wherein the capping layer is formed of a material containing SiO₂.

10. The method according to claim 1, wherein the diffusion barrier layer is formed of SiN or SiCN.

11. A method for forming a dual damascene pattern, comprising:
forming a first insulation layer on a substrate;
performing a plasma process on a surface of the first insulation layer; and
forming a second insulation layer on the first insulation layer.

12. The method according to claim 11, wherein the first insulation layer is formed of a material having a low dielectric constant.

13. The method according to claim 12, wherein the material having the low dielectric constant contains carbon.

14. The method according to claim 13, wherein performing a plasma process removes carbon from the material having the low dielectric constant.

15. The method according to claim 12, wherein the material having the low dielectric constant is SiOC.

16. The method according to claim 11, wherein the plasma process uses an inert gas.

17. The method according to claim 16, wherein the inert gas is He or Ar.

18. The method according to claim 11, wherein the plasma process uses O₂ or H₂.

19. The method according to claim 11, wherein the second insulation layer is formed of a material containing SiO₂.

20. The method according to claim 11, wherein performing a plasma process increases an adhesive force associated with the second insulation layer.
